(19) United States
(12) Patent Application Publication
(10) Pub. No.: US 2018/0375531 A1
(43) Pub. Date: Dec. 27, 2018

(54) DECODING CIRCUIT AND METHOD FOR QUASI-CYCLIC LOW-DENSITY PARITY-CHECK CODES

(71) Applicant: MStar Semiconductor, Inc., Hsinchu Hsien (TW)

(72) Inventor: Yu Hsien KU, Hsinchu Hsien (TW)

(21) Appl. No.: 15/691,857

(22) Filed: Aug. 31, 2017

(30) Foreign Application Priority Data
Jun. 21, 2017 (TW) 106120678

(51) Int. Cl. H03M 13/11; H03M 13/00

(52) U.S. Cl. CPC H03M 13/1131; H03M 13/616; H03M 13/116

(57) ABSTRACT

A decoding method for quasi-cyclic low-density parity-check codes is applied to a check matrix and multiple sets of transmission data. The check matrix includes N sub-matrices. The decoding method uses w (w<360) decoding units to perform decoding, and includes steps of: sending w sets of transmission data corresponding to a first block of a first sub-matrix to the w decoding units for decoding; and after completely decoding the w sets of transmission data corresponding to the first block of the first sub-matrix, sending w sets corresponding to a first block of a second sub-matrix to the w decoding units for decoding.

This application claims the benefit of Taiwan application Serial No. 106120678, filed on Jun. 21, 2017, the subject matter of which is incorporated herein by reference.

### BACKGROUND OF THE INVENTION

### Field of the Invention

The invention relates in general to low-density parity-check (LDPC) codes, and more particularly to a decoding circuit and method for quasi-cyclic low-density parity-check (QC-LDPC) codes.

### Description of the Related Art

Low-density parity-check (LDPC) codes are often used in communication systems to enhance the accuracy rate of data transmission. A transmitter multiplies original data to be transmitted by a generate matrix to generate transmission data longer than the original data. A receiver decodes the transmission data according to a check matrix to restore the original data. In practice, the receiver decodes the transmission data by an iterative operation. It is thus known that, the decoding operation of LDPC codes involves a colossal amount of computation. Therefore, there is a need for a solution that attends to both circuit costs and operation performance for the related field.

### SUMMARY OF THE INVENTION

In view of issues of the prior art, it is an object of the present invention to provide a decoding circuit and method for quasi-cyclic low-density parity-check (QC-LDPC) codes to enhance operation performance.

The present invention discloses a decoding circuit for QC LDPC codes. The decoding circuit includes: a memory, storing a check matrix and multiple sets of transmission data, wherein the check matrix includes N sub-matrices; w decoding units, where w<360; and a controller, coupled to the memory and the w decoding units, decoding the transmission data sent to the w decoding units according to the check matrix and sequences of: sending w sets of transmission data corresponding to a first block of a first sub-matrix to the w decoding units for decoding; and after completely decoding the w sets of transmission data corresponding to the first block of the first sub-matrix, sending w sets of transmission data corresponding to a first block of a second sub-matrix to the w decoding units for decoding.

The present invention further discloses a decoding method for QC LDPC codes applied to a check matrix and multiple sets of transmission data. The check matrix includes N sub-matrices. The decoding method uses w (w<360) decoding units for decoding and includes steps of: sending w sets of transmission data corresponding to a first block of a first sub-matrix to the w decoding units for decoding; and after completely decoding the w sets of transmission data corresponding to the first block of the first sub-matrix, sending w sets of transmission data corresponding to a first block of a second sub-matrix to the w decoding units for decoding.

Compared to conventional technologies, the decoding circuit and method for QC-LDPC of the present invention use simple circuits to achieve decoding operations as well as performance at the same time.

The above and other aspects of the invention will become better understood with regard to the following detailed description of non-limiting embodiments. The following description is made with reference to the accompanying drawings.

### BRIEF DESCRIPTION OF THE DRAWINGS

FIG. 1 is a schematic diagram of a decoding circuit in a low-density parity-check (LDPC) decoding circuit according to an embodiment of the present invention;

FIG. 2 is a schematic diagram of a decoding schedule of a check matrix H according to an embodiment of the present invention;

FIG. 3 is a schematic diagram of a decoding circuit in an LDPC decoding circuit according to another embodiment of the present invention;

FIG. 4A to FIG. 4C are schematic diagrams of decoding schedules of a check matrix H according to an embodiment of the present invention; and

FIG. 5 is a flowchart of a decoding method for QC-LDPC codes according to an embodiment of the present invention.

### DETAILED DESCRIPTION OF THE INVENTION

The disclosure of this application includes a decoding circuit and method for quasi-cyclic low-density parity check (QC-LDPC) codes. In possible implementation, one person skilled in the art can select equivalent elements or steps to achieve the present invention based on the disclosure of the application; that is, the implementation of the present invention is not limited to the following embodiments.

In consideration of decoding performance, most LCPC decoders adopt parallel operation architecture. For example, a check matrix of a QC-LDPC includes multiple sub-matrices and is a 360*360 identity matrix. Thus, a QC-LDPC decoder mostly adopt 360 identical decoding circuits to perform parallel decoding operations on the check matrix.

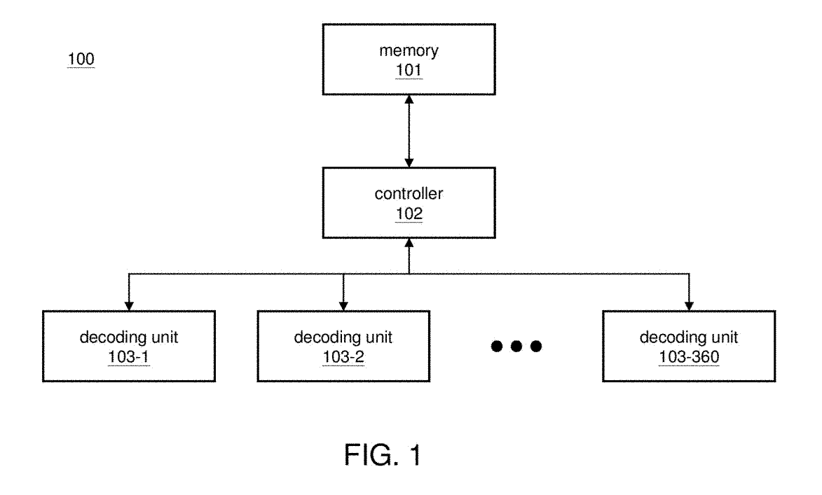

FIG. 1 shows a schematic diagram of a decoding circuit 100 in an LDPC decoder according to an embodiment of the present invention. As shown in FIG. 1, the decoding circuit 100 includes a memory 101, a controller 102, and 360 decoding units 103-1 to 103-360. The memory 101 stores a check matrix H and multiple sets of transmission data. According to the check matrix H, the controller 102 sends 360 sets of data of one sub-matrix respectively to the 360 decoding units 103-1 to 103-360 all at once to perform decoding to generate corrected data. Next, the controller 102 stores the corrected transmission data back to the memory 101 to complete the current round of correction for the 360 sets of transmission data. The decoding units 103-1 to 103-360 may be, for example but not limited to, a plurality of processor cores, or a plurality of engines of an application-specific integrated circuit (ASIC). Implementation details of the controller 102 and the decoding unit 103 and how the decoding unit 103 transmits data for decoding are generally known art, and shall be omitted herein for brevity.

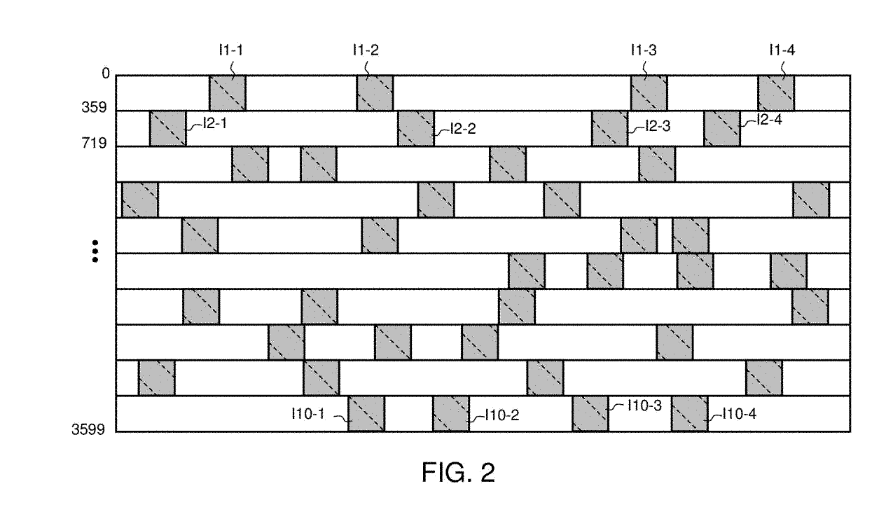

For example, FIG. 2 shows a schematic diagram of a decoding schedule for a check matrix H according to an embodiment of the present invention. As shown in FIG. 2, the check matrix H, in a unit of sub-matrices, is horizontally divided into 10 rows in a vertical direction, and includes four sub-matrices at each row. Each sub-matrix may be a shifted identity matrix. For example, in the check matrix H, the 1^{st} row in a unit of sub-matrices (i.e., 0^{th} to 359^{th} rows of the check matrix H) includes sub-matrices I1-1 to I1-4, the 2^{nd} row in a unit of sub-matrices (i.e., 360^{th} to 719^{th} rows of the check matrix H) includes sub-matrices I2-1 to I2-4, and so forth. In other words, the check matrix H includes a total of 10*4 sub-matrices, whereas other elements are all “0”. In this embodiment, the controller 102 sends 360 sets of transmission data corresponding to the sub-matrices respectively to the 360 decoding units 103-1 to 103-360 for decoding according to a decoding schedule {I1-1 to I1-4, I2-1 to I2-4, . . . , I10-1 to I10-4} each time, so as to complete the one round of correction on the transmission data.

After one round of correction on the transmission data is completed according to the decoding schedule, the decoding circuit 100 outputs the corrected data to a check circuit (not shown) to determine whether the correct data is converged. If not, the decoding circuit 100 again corrects the transmission data according to the above decoding schedule until the corrected data is converged.

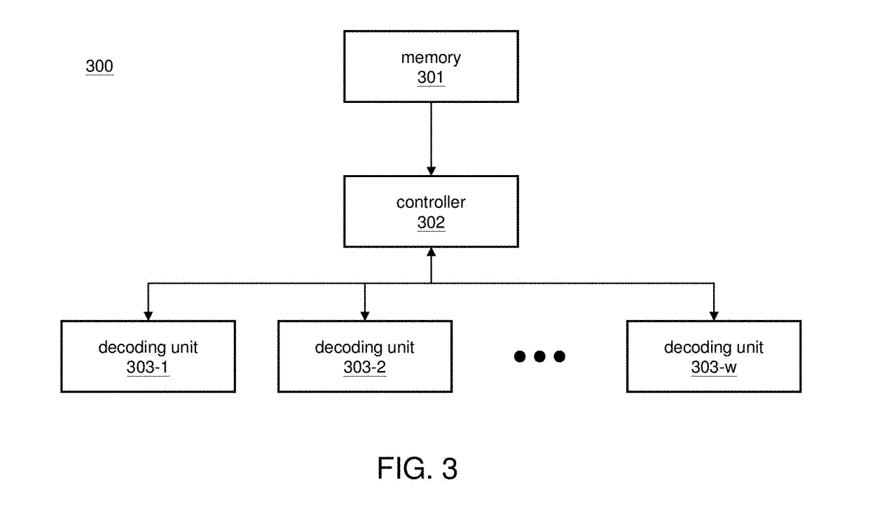

In one embodiment, the number of decoding units in the decoding circuit may be less than 360 to reduce the production costs of the decoding circuit. For example, FIG. 3 shows a schematic diagram of a decoding circuit 300 in an LDPC decoder according to another embodiment of the present invention. As shown in FIG. 3, the decoding circuit 300 includes a memory 301, a controller 302 and w (w<360) decoding units 303-1 to 303-w. In one embodiment, the number of decoding units in the decoding circuit 300 is q/p of the number of decoding units in the decoding circuit 100; that is,

$$w = 360 \times \frac{q}{p} ,$$

wherein p and q are relatively prime,

$$\frac{q}{p} < 1 ,$$

and p is a factor of p.

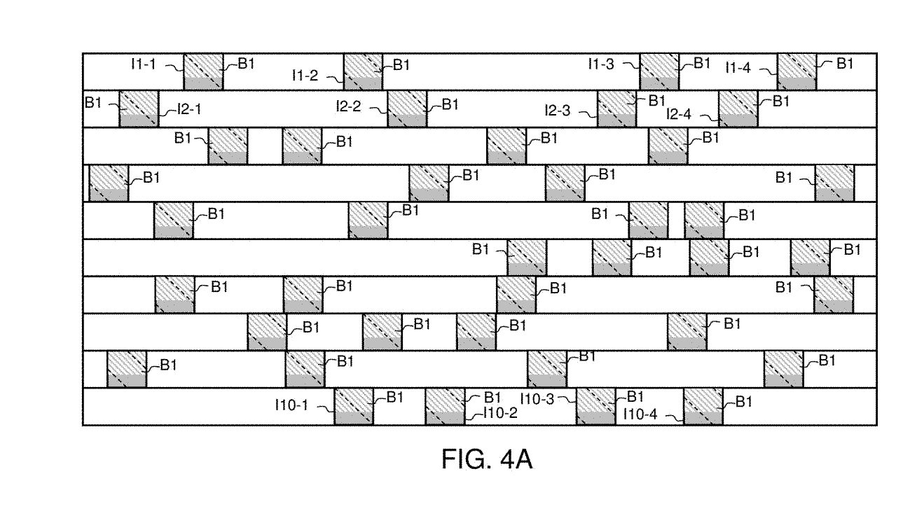

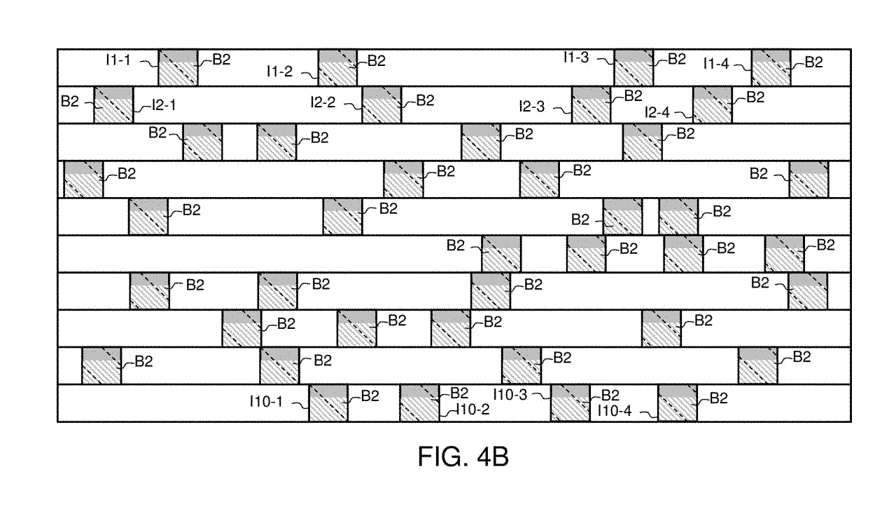

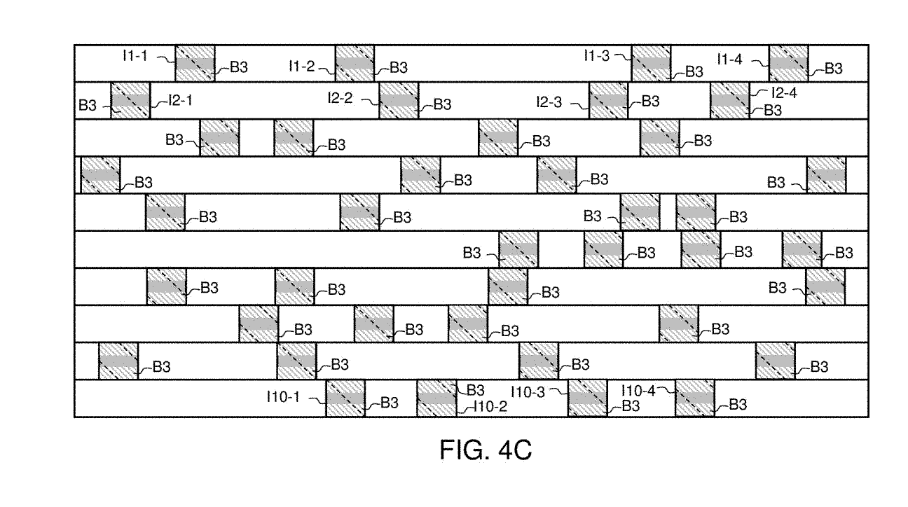

However, when the number of decoding units in the decoding circuit is smaller than 360, the decoding schedule of the check matrix needs to be especially designed, otherwise the decoding performance may be affected. For example, FIGS. 4A to 4C are schematic diagrams of decoding schedules of a check matrix H according to an embodiment of the present invention. Assuming that w=240 (i.e., q=2 and p=3), as shown in FIGS. 4A to 4C, a first block B1 (as shown by the shaded blocks in FIG. 4A) of each sub-matrix includes 1^{st} to 240^{th} rows of the sub-matrix, and a second block B2 (as shown by the shaded blocks in FIG. 4B) of each sub-matrix includes 121^{st} to 360^{th} rows, and a third block B3 (as the shaded blocks shown in FIG. 4C) of each sub-matrix includes 1^{st} to 120^{th} rows and 241^{st} to 360^{th} rows of the sub-matrix.

In this embodiment, the controller 302 may be a processor. However, the present invention is not limited to such example. In other embodiments, the controller 302 may be a specific-application integrated circuit (ASIC), a field programmable gate array (FPGA) or a digital signal processor (DSP).

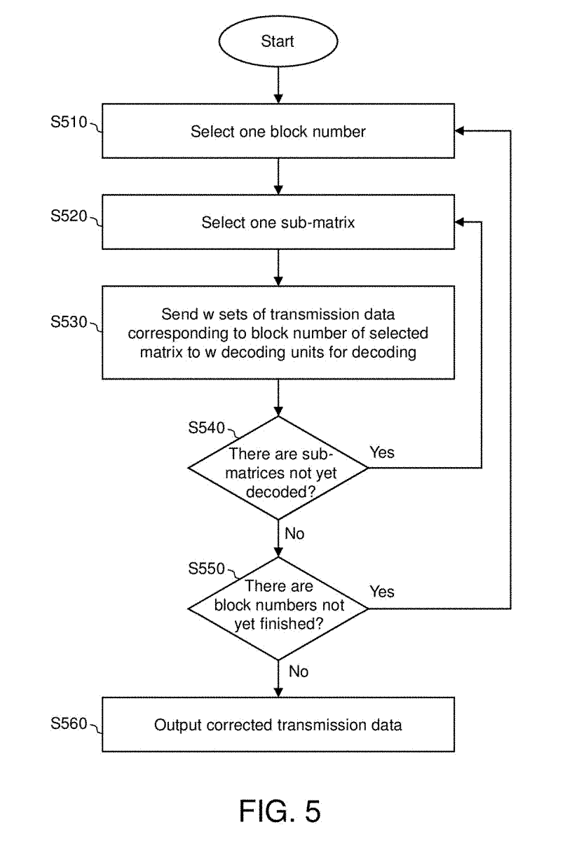

FIG. 5 shows a flowchart of a decoding method for QC LDPC codes according to an embodiment of the present invention. The decoding schedules in FIGS. 4A to 4C are described below with reference to FIG. 5. First, the controller 302 selects the first block (step S510). Next, according to a decoding schedule {I1-1 to I1-4, I2-1 to I2-4, . . . , I10-1 to I10-4}, 240 sets of transmission data corresponding to the first block B1 of the sub-matrix are respectively sent to the 240 decoding units 303-1 to 303-240 each time for decoding (i.e., steps S520 to S540, performed 40 times). According to a determination result indicating that there are blocks not yet decoded (step S550), the second block B2 is selected (step S510), and, according to a decoding schedule {I1-1 to I1-4, I2-1 to I2-4, . . . , I10-1 to I10-4}, 240 sets of transmission data corresponding to the second block B2 of the sub-matrix are respectively sent to the 240 decoding units 303-1 to 303-240 each time for decoding (i.e., steps S520 to S540, performed 40 times). Then, according to a determination result indicating there are blocks not yet decoded (step S550), the third block B3 is selected, and, according to a decoding schedule {I1-1 to I1-4, I2-1 to I2-4, . . . , I10-1 to I10-4}, 240 sets of transmission data corresponding to the third block B3 of the sub-matrix are respectively sent to the 240 decoding units 303-1 to 303-240 each time for decoding (i.e., steps S520 to S540, performed 40 times). The corrected transmission data is then outputted (step S560) to a check circuit (not shown) to determine whether the corrected data is converged. If the corrected data is not converged, the decoding circuit again corrects the transmission data according to the above decoding schedule until the corrected transmission data is converged.

It should be noted that, compared to the controller 102 that outputs the corrected transmission data after one round of correction is performed on the transmission data to determine whether the corrected transmission data is converged, the controller 302 only outputs the corrected transmission data after every two rounds of correction to determine whether the corrected transmission data. Thus, the number of times of convergence determination can be reduced to accelerate the convergence speed of transmission data to further enhance the decoding performance.

Further, in each decoding process, the controller 302 does not send transmission data corresponding to different sub-matrices to the 240 decoding units 303-1 to 303-240 (e.g., not sending the 120 sets of transmission data corresponding to the matrix I1-1 to the decoding units 303-1 to 303-120, and the 120 sets of transmission data corresponding to the matrix I1-2 to the decoding units 303-121 to 303-240 to simultaneously decode the transmission data corresponding to different sub-matrices) to enhance the decoding performance. More specifically, because of how the storage method of the transmission data in the memory 301 is designed, the memory 301 is only accessed once when the transmission data corresponding to the same sub-matrix is read or stored, and the memory 301 is accessed for more than once when the transmission data corresponding to different sub-matrices is read or stored. Therefore, if the 240 decoding units 303-1 to 303-240 simultaneously decodes the transmission data corresponding to two sub-matrices, the controller 302 needs to access the memory 301 four times (accessing twice for reading and accessing twice for storing). As such, the decoding performance of the decoding circuit 300 is reduced.

The number of rows of the check matrix H and the number of sub-matrices included in each row in the above description are in exemplary values, and are not to be construed as limitations to the present invention.

One person skilled in the art can understand implementation details and variations of the method of the present invention based on the disclosure on the device of the present invention, and such details shall be omitted herein. While the invention has been described by way of example and in terms of the embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A decoding circuit for quasi-cyclic low-density parity-check (QC-LDPC) codes, comprising:
a memory, storing a check matrix and a plurality of sets of transmission data, wherein the check matrix includes N sub-matrices;
w decoding units, where w<360; and
a controller, coupled to the memory and the w decoding units, sending the transmission data according to following sequences to the w decoding units for decoding:
sending w sets of transmission data corresponding to a first block of a first sub-matrix to the w decoding units for decoding; and
after completely decoding the w sets of transmission data corresponding to the first block of the first sub-matrix, sending w sets of transmission data corresponding to a first block of a second sub-matrix to the w decoding units for decoding.

2. The decoding circuit according to claim 1, wherein the controller does not transmit the remaining (360−w) sets of transmission data corresponding to the first sub-matrix to the w decoding units for decoding before sending the w sets of transmission data corresponding to the first block of the second sub-matrix.

3. The decoding circuit according to claim 1, wherein the controller further transmits w sets of transmission data corresponding to a second block of the first sub-matrix to the w decoding units for decoding after completely decoding the w*N sets of transmission data corresponding to the first block of the N sub-matrices, wherein the first block and the second block are at least partially non-overlapping.

4. The decoding circuit according to claim 1, wherein
$$w = 360 \times \frac{q}{p} , p$$
and q are positive integers and are relatively prime,
$$\frac{q}{p} < 1 ,$$
p is a factor of 360, and the decoding circuit outputs corrected transmission data to determine whether convergence is achieved only after the decoding circuit has performed q rounds of correction on the plurality of sets of data.

5. A decoding method for quasi-cyclic low-density parity-check (QC-LDPC) codes, applied to a check matrix and a plurality of sets of transmission data, the check matrix comprising N sub-matrices, the decoding method using w decoding units for decoding and comprising:
sending w sets of transmission data corresponding to a first block of a first sub-matrix to the w decoding units for decoding; and
after completely decoding the w sets of transmission data corresponding to the first block of the first sub-matrix, sending w sets of transmission data corresponding to a first block of a second sub-matrix to the w decoding units for decoding;
wherein, w<360.

6. The decoding method according to claim 5, wherein, before sending the w sets of transmission data corresponding to the first block of the second sub-matrix, not transmitting the remaining (360−w) sets of transmission data corresponding to the first sub-matrix to the w decoding units for decoding.

7. The decoding method according to claim 5, further comprising:
after completely decoding the w*N sets of transmission data corresponding to the first block of the N sub-matrices, transmitting w sets of transmission data corresponding to a second block of the first sub-matrix to the w decoding units for decoding, wherein the first block and the second block are at least partially non-overlapping.

8. The decoding method according to claim 5, wherein
$$w = 360 \times \frac{q}{p} ,$$
p and q are positive integers and are relatively prime,
$$\frac{q}{p} < 1 ,$$
p is a factor of 360, and corrected transmission data is outputted to determine whether convergence is achieved is only after q rounds of correction have been performed on the plurality of sets of data.
